(19) United States
(12) Patent Application Publication
(10) Pub. No.: US 2005/0269577 A1
(43) Pub. Date: Dec. 8, 2005

(54) Surface treatment method and surface treatment device

(75) Inventors: Tetsuzo Ueda, Osaka (JP); Daisuke Ueda, Osaka (JP)

Correspondence Address: GREENBLUM & BERNSTEIN, P.L.C., 1950 ROLAND CLARKE PLACE, RESTON, VA, 20191, US

(73) Assignee: Matsushita Electric Industrial co., Ltd., Osaka (JP)

(21) Appl. No.: 11/146,036

(22) Filed: Jun. 7, 2005

(30) Foreign Application Priority Data
Jun. 8, 2004 (JP) 2004-169724

(51) Int. Cl. H01L 27/15

(52) U.S. Cl. 257/80

(57) ABSTRACT

The present invention is conceived in order to accomplish an object of providing a surface treatment method and a surface treatment device that can planarize, at high speed, the surface of a nitride semiconductor with an excellent evenness. The surface treatment device includes an electrolyte supply port 15 for supplying a KOH electrolyte 14 containing fine metal particles and an abrasive, a storage container 40 having an opening on the top surface and is for storing the KOH electrolyte 14 supplied from the electrolyte supply port 15, a wafer holder 12 for fixing the GaN substrate 11 and bringing the surface of the GaN substrate 11 into contact with the KOH electrolyte 14 by impregnating the surface of the substrate into the KOH electrolyte 14 in the storage container 40 from above, a load 13 placed on the wafer holder 12, a device housing 16, a polishing pad 17 for polishing the surface of the GaN substrate 11 and an ultraviolet light source 42.

### BACKGROUND OF THE INVENTION

(1) Field of the Invention

The present invention relates to a substrate surface treatment method and a substrate surface treatment device that can be applied in manufacturing processes of integration circuits. Integration circuits include a semiconductor laser element, a light emitting diode, a field effect transistor and the like that are made from, for example, a nitride semiconductor. The present invention especially relates to a substrate surface planarization method and a substrate surface planarization device.

(2) Description of the Related Art

A GaN system nitride semiconductor (generally represented as InGaAlN) has a wide band gap, for example, the band gap of GaN at room temperature is 3.4 eV. The material can realize light-emitting diodes with a high power output in the blue and green visible region or within the wavelength range of ultraviolet rays. Such blue and green light-emitting diodes and white high-power-output light emitting diodes made in combination with fluorescent materials have already become commercial and been widely used. Also, with a view to using them as light sources for next-generation high-density optical disc system (Blu-ray Disc), the research and development of violet blue semiconductor laser elements made from this nitride semiconductor has been actively carried out. Also, the research and development of nitride semiconductors has been actively carried out. This is because they have features of a high-saturation drift velocity and a high breakdown voltage and because it is considered that they are promising as materials for future high-frequency and high-power-output electronic devices.

In order to realize the crystal growth of a nitride semiconductor, the Metal Organic Chemical Vapor Deposition Method (MOCVD method) is widely used. The crystal growth has been generally realized on a sapphire substrate so far, which entails the following three problems. Firstly, a crystal defect is generated because of lattice mismatch between a sapphire substrate and a GaN layer. Secondly, a sapphire substrate has a bad thermal dissipation. Lastly, the size of a chip that is made using a sapphire substrate becomes inevitably big because a sapphire substrate is an insulation substrate and therefore it is impossible to form electrodes on the both sides of a substrate. In order to solve this problem, a GaN substrate has been developed, the GaN substrate being obtainable by forming a GaN thick film on a host substrate using the Hydride Vapor Phase Epitaxy (HVPE method) and separating or removing the host substrate from the GaN layer. Further, a device structure has been formed on the GaN layer. Also, as a method for separating a GaN epitaxial growth layer from a sapphire substrate, a method called laser lift-off method has been proposed. The laser lift-off method includes: (i) dissolving the GaN as an interface by irradiating a high-power-output laser with a short wavelength ultraviolet rays through the back surface of the sapphire substrate on which the GaN epitaxial growth layer has not yet been formed; and (ii) separating the GaN epitaxial growth layer from the substrate. At this time, the surface of the crystal growth GaN layer, which is realized using the HVPE method, is badly uneven. Therefore, in the case of epitaxially growing a device structure on the GaN layer next, there is a need to planarize the surface of the GaN layer at an atom level. For example, refer to Mat. Res. Soc. Symp. Proc. Vol. 639 (2001) G5. 6. 1-G. 5. 6. 10, by A. Usui et al. Also, the surface of the GaN layer becomes rough after the earlier-described laser lift-off. This is because the unevenness of the laser light irradiated through the back surface of the sapphire substrate or the crystalline unevenness around the interface between the GaN layer and the sapphire substrate. For example, refer to Applied Surface Science Vol. 216 (2003) p. 512-518, T. Ueda et al. Therefore, in the case of performing the process of forming a device in the surface of the GaN layer after laser lift-off, it is desirable that the surface of the GaN layer be more planarized, in other words, the surface of the GaN layer needs to be planarized like the crystal growth surface of the GaN layer. After that, the earlier-described planarization is generally performed through polishing in which solution including an abrasive such as diamond powder is used.

The planarization method of the surface of a conventional GaN layer will be described below.

FIG. 1 is a cross-sectional view of a GaN substrate surface treatment device, showing the structure of the device in a conventional example.

This surface treatment device is a polishing device that planarizes the surface of a GaN substrate. The surface treatment device includes a wafer holder 2 for fixing a GaN substrate 1, a load 3 that is put on the wafer holder 2, an electrolyte supply port 5 through which an electrolyte 4 including an abrasive is supplied, a device housing 6, and a polishing pad 7 that is placed on the device housing 6.

The planarization process by the surface treatment device with the above-described structure is performed in the following way: (i) the GaN substrate 1 is fixed on the wafer holder 2 using, for example, wax, (ii) the electrolyte 4 including an abrasive such as diamond powder is supplied to between the GaN substrate 1 and the polishing pad 7, and then (iii) the GaN substrate 1 is rotated placing load on the GaN substrate 1 so that the surface of the GaN substrate 1 can be polished and planarized by the abrasive. The surface of the GaN substrate after the laser lift-off is also planarized in the same way. Note that this planarization method is used in the following processes of: sliming down the GaN substrate; and making the surface of the GaN substrate into a mirror surface; in addition, in the case where there is a need to planarize the surface of a GaN substrate formed using the HVPE method in the device process.

### SUMMARY OF THE INVENTION

However, in the surface treatment method and the surface treatment device that are conventionally applied for planarization of a GaN suraface, it is impossible to realize an excellent surface planarization at an atom level. This is because the GaN surface is planarized only by polishing with an abrasive.

At this time, a conceivable surface treatment method for planarizing that GaN surface at an atom level is a planarization method of wet chemical etching. More specifically, the wet chemical etching method includes generating holes on the GaN surface, oxidizing the GaN surface, and then removing the resulting oxide. However, it is impossible to easily realize a high-speed planarization because it is generally difficult to perform wet etching of the GaN surface. In order to enable a higher speed etching, there is a need to perform etching after forming electrodes on the GaN surface, placing electrodes in a solution such as KOH and making a current flow in the solution. Consequently, it is impossible to easily perform, at high speed, such planarization of the surface of the GaN layer that can make the surface beautifully even, although such planarization can be realized in the case of performing Chemical Mechanical Polishing (CMP) processing. The CMP processing is for performing polishing (chemical polishing etching) using an etching solvent that is widely used in the Si substrate or Si integrated circuit generation process or the last process of substrate polishing.

Therefore, the present invention is conceived considering the above-described technical problem, and an object of the present invention is to provide a surface treatment method and a surface treatment device that can realize, at high speed, nitride semiconductor surface planarization with an excellent evenness.

In order to solve the problem, the surface treatment method in the present invention, is for planarizing the surface of a substrate, the method including planarizing of the surface of the substrate by performing etching of the surface with an electrolyte containing fine metal particles in a way that the surface is brought into contact with the electrolyte.

Here, it is preferable that, in a first aspect of the present invention, the etching in the surface treatment method be performed together with irradiation of light on the surface of the substrate that is brought into contact with the electrolyte.

Also, it is further preferable that the electrolyte includes an abrasive and the etching of the surface is performed in combination with the polishing of the surface.

In this way, in the case of planarizing the surface of a nitride semiconductor substrate, the irradiation of ultraviolet rays on the substrate surface that is brought into contact with the electrolyte accelerates the formation of pairs of an electron and a hole on the substrate surface and the oxidization and dissolution of the nitride semiconductor. This makes it possible to perform chemical etching, with a high etching rate, of the nitride semiconductor although it has been extremely difficult to realize by using only an electrolyte. Consequently, it becomes possible to perform, at high speed, such planarization of the nitride semiconductor surface that can make the surface beautifully even. Also, it is possible to perform chemical polishing etching of the nitride semiconductor surface by performing etching and polishing of the surface in combination. Consequently, it becomes possible to realize planarization of a nitride semiconductor surface at further higher speed. Also, since there is no need to place electrodes on the substrate in order to realize a higher etching rate, it becomes possible to easily realize a high-speed planarization.

Also, it is preferable that, in a second aspect of the present invention, in the surface treatment method, energy of the light to be irradiated on the surface of the substrate be greater than a band gap of the substrate.

In this way, the light irradiation triggers the formation of pairs of an electron and a hole on the substrate, and then it becomes possible to perform chemical etching of a nitride semiconductor at a higher etching rate. Consequently, it becomes possible to perform, at high speed, such planarization of the nitride semiconductor surface that can make the surface beautifully even.

Also, it is preferable that, in the second aspect of the present invention, in the surface treatment method, the light to be irradiated on the surface of the substrate be a laser light.

In this way, it is possible to increase the output of light to be irradiated on the substrate surface and to increase the number of pairs of an electron and a hole. This makes it possible to perform chemical etching of the nitride semiconductor with a further higher etching rate. Consequently, it becomes possible to perform planarization of the nitride semiconductor surface at a further high speed.

Also, it is preferable that, in the first aspect of the present invention, in the surface treatment method, the surface of the substrate be brought into contact with the electrolyte by impregnating the surface of the substrate into the electrolyte or by bringing the surface of the substrate into contact with a surface of a holding member into which the electrolyte is infiltrated.

In other words, it is preferable that the means for bringing a part of the substrate into contact with an electrolyte be one of the following: the means for impregnating the substrate; the means for spray penetrating the electrolyte on the substrate; and the means for polishing the substrate using a holding member into which an electrolyte is infiltrated. Also, it is further preferable that light be irradiated towards the surface on which the substrate and the electrolyte are brought into contact with each other when bringing the part of the substrate into contact with the electrolyte.

In the case of planarizing the nitride semiconductor substrate surface in this way, it becomes possible to realize, at high speed, such planarization of the nitride semiconductor surface that can make the surface beautifully even. This is because the storage of holes are facilitated because of the internal electric field in proximity to the nitride semiconductor surface.

Also, it is preferable that, in the first aspect of the present invention, in the surface treatment method, the fine metal particles be made of one of Pt, Au and Ag.

In this way, it becomes difficult for fine metal particles to release electrons, which makes it possible to perform chemical etching of the nitride semiconductor at a further higher etching rate. Consequently, it becomes possible to perform planarization of the nitride semiconductor surface at a further higher speed.

Also, it is preferable that, in the first aspect of the present invention, in the surface treatment method, an electrically conductive member be placed in the electrolyte, and the etching of the surface of the substrate is performed together with application of voltage to between the surface and the electrically conductive member.

In this way, in the case of planarising a P-type semiconductor substrate by applying plus voltage to the substrate, since holes are stored in the substrate surface, the concentration of holes in proximity to the substrate surface increases and it becomes possible to increase the etching speed.

Also, it is preferable that, in the first aspect of the present invention, in the surface treatment method, the etching of the surface of the substrate be performed together with heating of the substrate.

In this way, the substrate is heated resulting in reducing the degree of warpage, which makes it possible to perform planarization with excellent evenness of the substrate surface. Also, since the electrolyte is also heated at the same time when the substrate is heated, it becomes possible to accelerate chemical reaction in the electrolyte and increase the etching speed.

Also, it is preferable that, in the first aspect of the present invention, in the surface treatment method, the substrate be made of a compound semiconductor including nitrogen.

In this way, it becomes possible to perform, at high speed, such planarization of the substrate surface that can make the surface beautifully even in the manufacturing process of the GaN semiconductor device such as a visible region ray or ultraviolet ray emitting diode element, violet blue semiconductor laser element, and a high speed and high power output device for use under high temperature.

Also, it is preferable that the part of the substrate be brought into contact with the electrolyte containing fine metal particles. In addition to this, it is further preferable that etching or polishing of the part of the substrate brought into contact with the electrolyte be performed.

In this way, it becomes possible to facilitate the storage of holes on the GaN surface and improve the etching speed of the surface.

Also, in the process of bringing the substrate into contact with the electrolyte containing fine metal particles, it is preferable that the substrate or the electrolyte be heated.

In this way, in the case where a difference in thermal expansion coefficients comes into existence between the substrate and the epitaxial growth layer formed on the substrate and the substrate is warped, it becomes possible to reduce the warpage of the substrate and to planarize the substrate evenly by heating the substrate.

Heating the electrolyte also makes it possible to accelerate chemical reaction in etching and to realize surface etching at further higher speed.

Also, it is preferable that the substrate be made up of a single crystalline substrate and a semiconductor film that has been epitaxially grown on this single crystalline substrate.

In this way, it becomes possible to perform, at high speed, surface treatment that can realize an excellent evenness when planaraizing the rough epitaxial growth surface or sliming down the epitaxial growth layer in which the device structure such as a semiconductor laser element is formed.

Also, it is preferable that the substrate is made up of at least two layers of materials with a different thermal expansion coefficient.

In this way, in the case where the substrate is made up of a sapphire substrate and a GaN system semiconductor film that is formed on the substrate, in other words, in the case where the substrate is warp because of the difference in thermal expansion coefficients, heating the substrate makes it possible to reduce the degree of warpage of the substrate and to planarize the substrate evenly.

Also, it is preferable that the substrate is made up of (i) one of sapphire, SiC, GaN, AlN, MgO, LiGaO₂, LiAlO₂ and a mixed crystal of LiGaO₂ and LiAlO₂, and (ii) a compound semiconductor including nitride that is formed on the substrate.

In this way, a GaN system semiconductor device with an excellent crystallinity can be formed, which makes it possible to realize a GaN system semiconductor device such as a visible region ray or ultraviolet ray emitting diode element, a violet blue semiconductor laser element, and a high speed and high power output device for use under high temperature.

Also, it is preferable that a compound semiconductor including nitride be formed as the top layer of the substrate, and the light to be irradiated is one of the following: a mercury-vapor lamp, a He—Cd laser, the harmonic generation of YAG laser and Excimer laser.

In this way, it is possible to form many pairs of an electron and a hole on the GaN system semiconductor surface, which makes it possible to realize surface etching at further higher speed.

Also, it is preferable that the substrate be made of a substrate that allows the ultraviolet rays to pass through and a nitride semiconductor layer that is formed on the substrate. Under the above condition the following steps for planalization are performed: (i) ultraviolet rays is irradiated from the side on which the nitride semiconductor is not formed of the substrate that allows the ultraviolet rays to pass through; (ii) the nitride semiconductor layer is separated from the substrate by dissolving the nitride semiconductor at the interface between the substrate and the nitride semiconductor layer; and (iii) the surface of the nitride semiconductor layer that is formed and brought into contact with the substrate is finally planarized.

In this way, it becomes possible to perform, at high speed, such planarization of the GaN system semiconductor surface that can make the surface beautifully even after the so-called laser lift-off process. The laser lift-off process is the process for separating, for example, a GaN system semiconductor device layer that is formed on a sapphire substrate from the substrate by irradiating a short-wavelength and high-power-output pulse laser such as KrF Excimer Laser through the back surface of the sapphire substrate.

Also, the present invention can be realized as a surface treatment device for planarizing the surface of a substrate, the device including: a storage unit for storing an electrolyte containing fine metal particles; and a contact unit for bringing the surface of the substrate into contact with the electrolyte.

Here, it is preferable that the surface treatment device further include a light source for irradiating light on the surface. Also, it is preferable that, in an eleventh aspect of the present invention, in the surface treatment device, the storage unit be a storage container having an opening on the top surface and be for storing the electrolyte, and the contact unit fixes the substrate and impregnates the surface of the substrate into the electrolyte in the storage container. Also, it is preferable that, in the eleventh aspect of the present invention, in the surface treatment device, the storage unit be a holding member into which the electrolyte is infiltrated, and the contact unit fixes the substrate and brings the surface of the substrate into contact with the holding member.

In this way, it becomes possible to perform chemical etching of a nitride semiconductor with a high etching rate although performing chemical etching in which only an electrolyte is used has been extremely difficult. This makes it possible to perform, at high speed, such planarization of the surface of a nitride semiconductor that can make the surface beautifully even. Also, since there is no need to place electrodes on the substrate in order to realize a high etching rate, such high-speed planarization can be easily performed.

Also, it is preferable that, in a twelfth aspect of the present invention, in the surface treatment device, the light source be a laser light source.

In this way, the output of light to be irradiated on the substrate increases, which makes it possible to form many pairs of an electron and a hole on the substrate. This makes it possible to perform chemical etching of the nitride semiconductor with a further higher etching rate. Consequently, it becomes possible to perform planarization of the nitride semiconductor surface at a further higher speed.

Also, it is preferable that, in the eleventh aspect of the present invention, the surface treatment device include a polishing pad for polishing the surface of the substrate, the pad being placed facing the surface of the substrate.

In this way, it becomes possible to perform chemical polishing etching of the surface of the nitride semiconductor. This makes it possible to realize planarization of the surface of the nitride semiconductor at a further higher speed.

Also, it is preferable that, in the eleventh aspect of the present invention, the surface treatment device further include a polishing pad for polishing the surface of the substrate, the pad being placed facing the surface of the substrate, and a light source for irradiating light on the surface of the substrate, the light source being placed opposite the substrate across the polishing pad, the polishing pad in the device has an opening.

In this way, it becomes possible to perform light irradiation in proximity to the substrate, light intensity around the surface increases and the number of pairs of an electron and a hole formed on the substrate surface also increases. This makes it possible to realize planarization of the surface of a nitride semiconductor at a further higher speed.

Also, it is preferable that, in the eleventh aspect of the present invention, in the surface treatment device, the storage unit be a storage container having an opening on the top surface and be for storing the electrolyte, the contact unit fixes the substrate and impregnates the surface of the substrate into the electrolyte in the storage container, the surface treatment device further includes: a polishing pad for polishing the surface of the substrate, the polishing pad being placed facing the surface; and a light source for irradiating the light on the surface of the substrate, the light source being placed at a side of the storage container; and a side surface of the storage container is transparent to the light emitted by the light source.

In this way, using a high-output-power laser light as light to be irradiated on the substrate surface makes it possible to form a sufficient number of pairs of an electron and a hole even in the case where the light is irradiated horizontally the substrate. This eliminates the need to form openings of the polishing pad. Consequently, it becomes possible to realize a surface treatment device with a simpler structure.

Also, it is preferable that, in the eleventh aspect of the present invention, the surface treatment device further include: an electrically conductive polishing pad for polishing the surface of the substrate, the polishing pad being placed facing the surface; electrodes placed in contact with the substrate; and an electronic power supply for applying voltage to between the electrodes and the polishing pad.

In this way, in the case of planarizing a P-type semiconductor substrate by applying plus voltage to the substrate, it becomes possible to increase the etching speed. This is because holes are stored on the substrate surface resulting in the increase in the concentration of holes on the substrate surface.

Also, it is preferable that, in the eleventh aspect of the present invention, the surface treatment device further include a heater for heating the substrate.

In this way, the substrate is heated and the warpage of the substrate is reduced, which makes it possible to perform such planarization of the substrate surface that can make the surface beautifully even. Also, the electrolyte is heated at the same time when the substrate is heated, which makes it possible to accelerate chemical reaction in the electrolyte resulting in the increase in the etching speed.

Also, it is preferable that the polishing device include a wafer holder that fixes the substrate, a polishing pad placed in a way that the substrate is placed between the wafer holder and itself, and equipment for supplying the electrolyte containing fine metal particles to between the substrate and the polishing pad.

In this way, using fine metal particles made of metal that emits few electrons such as Pt makes it possible to accelerate the storage of holes on the GaN surface and to improve the surface etching speed in the case where, for example, a GaN surface is planarized.

Also, it is further preferable that the polishing device have equipment for supplying the electrolyte containing an abrasive.

In this way, it becomes possible to perform chemical etching and mechanical polishing at the same time, which makes it possible to realize planarization at a further higher speed.

As described up to this point, with the surface treatment method and the surface treatment device of the present invention, ultraviolet rays to be irradiated on the electrolyte containing fine metal particles and the nitride semiconductor surface can accelerate the formation of pairs of an electron and a hole on the nitride semiconductor surface and the dissolution of the nitride semiconductor, and thus it becomes possible to perform chemical polishing etching of the nitride semiconductor surface although performing chemical etching in which only an electrolyte is used has been extremely difficult. Consequently, it becomes possible to planarize the nitride semiconductor surface concurrently realizing high speed and high evenness. Also, heating the substrate to be planarized or the electrolyte makes it possible to perform planarization at a higher speed. In the case of planarizing, for example, a p-GaN surface by applying direct voltage to between the substrate and the polishing pad, the concentration of holes on the p-GaN surface increases, which consequently makes it possible to perform such a high-speed etching.

### FURTHER INFORMATION ABOUT TECHNICAL BACKGROUND TO THIS APPLICATION

The disclosure of Japanese Patent Application No. 2004-169724 filed on Jun. 8, 2004 including specification, drawings and claims is incorporated herein by reference in its entirety.

### BRIEF DESCRIPTION OF THE DRAWINGS

These and other objects, advantages and features of the invention will become apparent from the following description thereof taken in conjunction with the accompanying drawings that illustrate a specific embodiment of the invention. In the Drawings:

FIG. 1 is a cross-sectional view of a surface treatment device, showing the structure of the device in a conventional example;

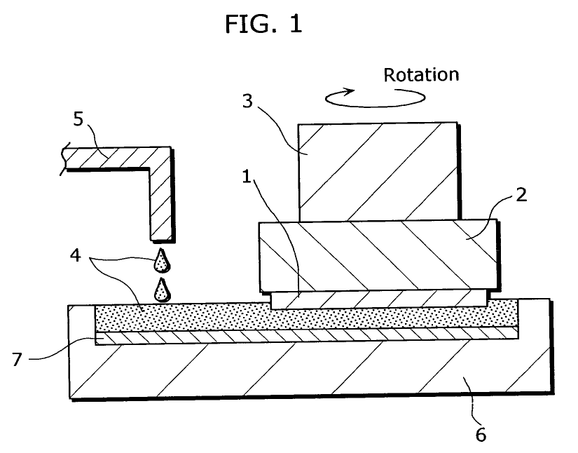

FIG. 2 is a cross-sectional view of a surface planarization device, showing the structure of the device in a first embodiment of the present invention;

FIG. 3 is a cross-sectional view of a surface planarization device, showing the structure of the device in a second embodiment of the present invention;

FIG. 4 is a cross-sectional view of a surface planarization device, showing the structure of the device in a third embodiment of the present invention;

FIG. 5 is a cross-sectional view of a surface planarization device, showing the structure of the device in a fourth embodiment of the present invention;

FIG. 6 is a cross-sectional view of a surface planarization device, showing the structure of the device in a fifth embodiment of the present invention; and

FIGS. 7A to 7H are cross-sectional views of surface emitting laser elements, indicating the manufacturing methods of the elements in a sixth embodiment of the present invention.

### DESCRIPTION OF THE PREFERRED EMBODIMENT(S)

The surface treatment method and the surface treatment device in the embodiments of the present invention will be described with reference to figures.

### First Embodiment

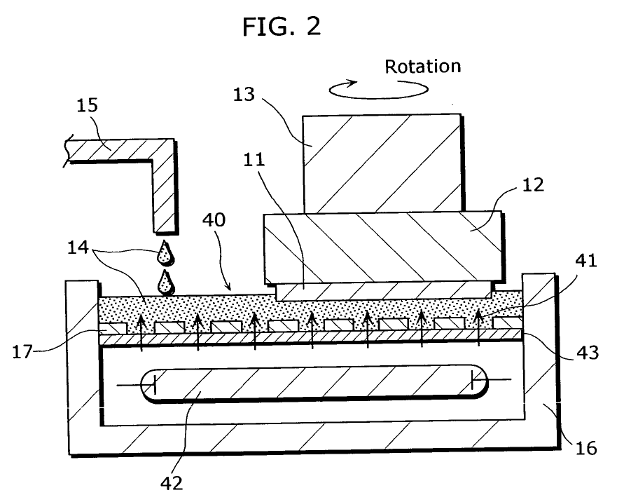

FIG. 2 is a cross-sectional view of a surface planarization device, showing the structure of the device in a first embodiment of the present invention.

This surface planarization device is for planarizing the surface of a GaN substrate 11. The surface planarization device includes (i) an electrolyte supply port 15 for supplying a KOH electrolyte 14 that is an alkaline electrolyte containing an abrasive such as fine Pt particles or diamond powder, (ii) a storage container 40 having an opening on the top surface and is for storing the KOH electrolyte 14 supplied from the electrolyte supply port 15, (iii) a wafer holder 12 for fixing and bringing the GaN substrate 11 into contact (become wet) with the KOH electrolyte 14 in the storage container 40 by impregnating the surface of the GaN substrate 11 into the KOH electrolyte 14 from above, (iv) a load 13 that is placed on the wafer holder 12, the load 13 and the wafer holder 12 constituting the contact unit, (v) a device housing 16, (vi) a polishing pad 17, for polishing the surface of the GaN substrate 11, placed on the quartz board 43 that constitutes the back surface of the storage container 40, and (vii) an ultraviolet source 42 placed below the storage container 40 inside the device housing 16. Note that fine particles mean nanoparticles of 1 μm or less that are capable of keeping a good dispersion status.

The polishing pad 17 is placed facing the GaN substrate 11 to be polished, and it is made of, for example, a metal board or a resin such as a synthetic rubber on which fine openings are formed.

The ultraviolet rays 42 is a ultraviolet ray source such as a low pressure mercury vapor lamp placed opposite the GaN substrate 11 across the polishing pad 17. It irradiates ultraviolet rays 41 having energy greater than the band gap of the GaN substrate 11 on the GaN substrate 11 surface brought into contact with the KOH electrolyte 14. The quartz board 43 placed between the ultraviolet ray source 42 and the GaN substrate 11 is transparent to this ultraviolet rays 41, and the ultraviolet rays 41 that have passed through the quartz board 43 is irradiated on the surface of the GaN substrate 11 through the openings of the polishing pad 17.

The KOH electrolyte 14 in the storage container 40 is circulated or periodically exchanged through the exhaust port (not shown) of the storage container 40 and the electrolyte supply port 15.

Next, the surface planarization method in the first embodiment of the present invention will be described with reference to FIG. 2.

The surface planarization device having the above structure polishes the surface of the GaN substrate 11 so as to planarize the surface by (i) placing the GaN substrate 11 on the wafer holder 12 so that the side to be polished points downward and is fixed using a wax or the like, (ii) placing the load 13 on the GaN substrate 11 through the wafer holder 12, (iii) pressing the surface of the GaN substrate 11 on the polishing pad 17 inside the KOH electrolyte 14 in the storage container 40, and then (iv) rotating the wafer holder 12.

At this time, this surface planarization method is way different from a conventional surface planarization device in that the method of the present invention is for performing light etching (light wet etching) using fine Pt particles attached to the surface of the GaN substrate 11 by using the KOH electrolyte 14 including fine Pt particles as an electrolyte and irradiating ultraviolet rays 41 on the surface of the GaN substrate 11 in the KOH electrolyte 14 through the openings that are present in the polishing pad 17.

The mechanism of wet etching by irradiating light on or applying voltage to the GaN substrate 11 will be described below. According to C-Y. Fang et al. (refer to Jpn. J. Appl. Phys. Vol. 42(2203) pp. 4207-4212.), wet etching of GaN can be expressed in the following chemical equation:
GaN(s)→GaN(s)+e⁻+h⁺
2GaN*+6h⁺+3H₂O(1)→Ga₂O₃(s)+N₂(g)+6H⁺(a q)
Ga₂O₃(s)+3H₂O(1)→2Ga³⁺ (a q)+6OH⁺(a q)

In other words, when ultraviolet rays are irradiated on the GaN surface, pairs of an electron and a hole are formed on it, these holes and H₂O react with the GaN, resulting in oxidizing the GaN, and the resulting oxide of the GaN starts dissolving, in other words, the etching of the GaN progresses. In the case of a n-type GaN, it is possible to facilitate etching by releasing electrons. In contrast, in the case of an p-type GaN, it is possible to facilitate etching by, for example, applying bias so that the GaN substrate 11 side has plus potential and storing holes around the surface of the GaN substrate 1 (for example, refer to J•W. Yang et al. Electronics Letters Vol. 36(2000) p 88-90). In this embodiment, since fine Pt particles to be added to the KOH electrolyte 14 have a high electronegativity and difficult to emit electrons, in the case of an n-type GaN, it is possible to facilitate the storage of holes on the surface of the GaN substrate 11 and to facilitate causing chemical etching when the ultraviolet rays 41 are irradiated on the n-type GaN. Also, in the case of p-type GaN, the eariler-described fine Pt particles concurrently function as electrodes at the electrolyte side when voltage is applied, which consequently makes it possible to facilitate causing chemical etching.

Therefore, in the surface treatment method and by the surface treatment device in this embodiment, when polishing a GaN substrate surface, the GaN substrate surface is brought into contact with the alkaline electrolyte containing fine Pt particles, and ultraviolet rays are irradiated between the GaN substrate surface and the electrolyte through the openings of the polishing pad. Consequently, it becomes possible to facilitate the formation of pairs of an electron and a hole on the GaN substrate surface and the dissolution of the GaN. This makes it possible to perform chemical etching of the GaN at high speed although performing chemical etching in which only an electrolyte is used has been extremely difficult. In this way, it becomes possible to planarize the GaN substrate performing a high-speed etching and polishing of the surface in combination. This makes it possible to realize the surface planarization method and the surface planarization device that performs, at high speed, such planarization of the GaN surface that can make the surface beautifully even.

Note that, in the surface planarization method and the surface planarization device of this embodiment, it is possible to form, on the GaN layer, one of (i) an epitaxial growth layer in which a blue violet semiconductor laser element or the like is formed and (ii) a device structure such as a blue violet semiconductor laser element. Also, the surface planarization method and the surface planarization device in this embodiment may be used in the process of polishing and etching the side of the GaN substrate on which they are not formed so as to slim down the GaN substrate.

Also, here is an example case where fine Pt particles are used as fine metal particles included in the alkaline electrolyte in the surface planarization method and by the surface planarization device in this embodiment, but such particles are not limited to them. Any fine metal particles having the following feature will suffice: being made up of a metal element whose electronegativity is no less than 1 pauling; and being more difficult to ionize than hydrogen. For example, fine metal particles made of Au and Ag whose electronegativities are 2.4 pauling and 1.9 pauling respectively. In this way, since such fine metal particles are to be made of materials that are difficult to emit electrons, it is possible to facilitate the storage of holes on, for example, the GaN substrate surface and thus it is possible to realize the surface planarization method for performing planarization at a further higher speed and the surface planarization device that can perform planarization at a further higher speed.

Also, here is an example case where GaN substrate is used as the substrate to be planarized in the surface planarization method and by the surface planariztion device in this embodiment, but such a substrate is not limited to the GaN substrate. Any compound semiconductor will suffice as long as it includes nitrogen.

Also, the surface planarization device of this embodiment may have a mixing unit connected to the electrolyte supply port, the mixing unit being for mixing the electrolyte, an abrasive and fine metal particles. Also, the surface planarization device may have a dispersion maintenance unit for mixing the electrolyte so as to maintain an electrolyte status where the abrasive and fine metal particles are dispersed evenly in the electrolyte.

### Second Embodiment

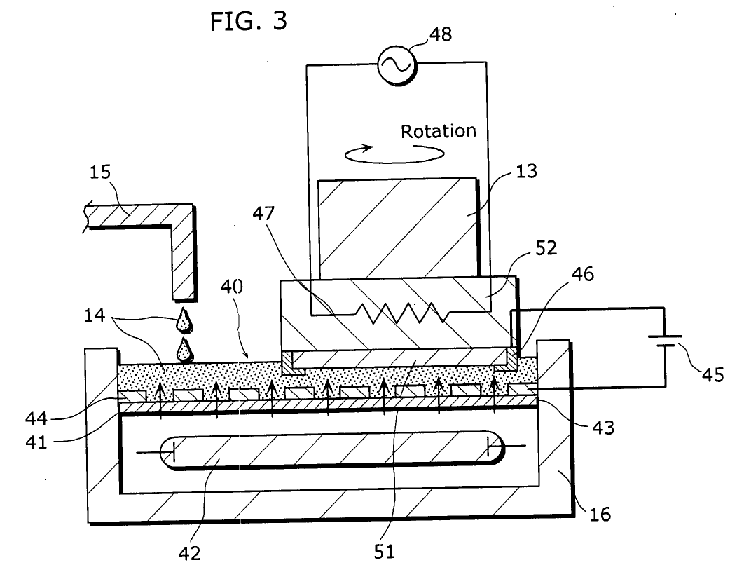

FIG. 3 is a cross-sectional view of a surface planarization device, showing the structure of the device in a second embodiment of the present invention.

This surface planarization device is for planarizing the surface of the GaN substrate 51. The surface planarization device includes (i) an electrolyte supply port 15 for supplying a KOH electrolyte 14 including fine Pt particles and an abrasive, (ii) a storage container 40, (iii) a wafer holder 52 for fixing the GaN substrate 51 and bringing the GaN substrate 51 into contact with the KOH electrolyte 14 in the storage container 40 by impregnating the surface of the GaN substrate into the electrolyte 14 from above, (iv) a load 13 that constitutes the contact unit together with the wafer holder 52, (v) a device housing 16, (vi) a polishing pad 44 for polishing the surface of the GaN substrate 51 placed on the quartz board 43 that constitutes the back surface of the storage container 40, (vii) an ultraviolet ray source 42 for irradiating ultraviolet rays 41 with energy lager than the band gap of the GaN substrate 51, (viii) electrode pins 46 placed in contact with the GaN substrate 51, and (ix) a power supply 45 for applying voltage to between the electrode pins 46 and the polishing pad 44. The GaN substrate 51 is structured by forming a GaN thin film on a sapphire substrate as a single crystal substrate using, such as, the Metal Organic Chemical Vapor Deposition (MOCVD) method.

The polishing pad 44 is placed facing the surface to be polished of the GaN substrate 51. The polishing pad 44 is an electrically-conductive member made of, for example, a metal board with fine openings.

The wafer holder 52 is attached to the substrate heater 47 connected with the heater power 48.

Next, the surface planarization method in a second embodiment of the present invention will be described with reference to FIG. 3.

The surface planarization device having the above structure polishes the surface of the GaN substrate 51 so as to planarize the surface by (i) placing the GaN substrate 51 on the wafer holder 52 so that the surface to be polished points downward and fixing the GaN substrate 51 using wax or the like, (ii) placing the load 13 on the GaN substrate 51 through the wafer holder 52, (iii) pressing the surface of the GaN substrate 51 on the polishing pad 44 in the KOH electrolyte 14, and (iv) rotating the wafer holder 52.

At this time, this surface planarization method is way different from the surface planarization method of the first embodiment in that the GaN substrate 51 is heated by the substrate heater 47 of the wafer holder 52 so as to reduce the warpage of the GaN substrate. In general, in the case of forming the GaN substrate 51 by epitaxially growing a GaN thin film on a sapphire substrate, the GaN substrate 51 warps like a convex because of the difference in the thermal expansion coefficients of both the materials. However, in the surface planarization method of this embodiment, the GaN substrate 51 is heated by the substrate heater 47 up to, for example, approximately 500° C. during the polising in order to reduce the warpage of the GaN substrate 51 and to make the surface planarized. Consequently, it becomes possible to perform etching and polishing with an excellent evenness on the GaN substrate 51 surface. Also, the reduction in the stress given to the GaN substrate 51 during the polisihng makes it possible to prevent the substrate from cracking or the like during the polishing. Note that, as for wax or a binder for fixing the GaN substrate 51 on the wafer holder 52, such wax or a binder that has heat resistance of 500° C. or more and can hold the GaN substrate 51 even at such a temperature is selected to be used.

Also, this surface planarization method is different from the surface planarization method of the first embodiment in that chemical wet etching is further accelerated by applying direct voltage coming from the power supply 45 to between the electrode pins 46 placed in contact with the GaN thin film of the GaN substrate 51 and the polishing pad 44 made of an electrically conductive material. In the case where p-type GaN thin film is formed on the GaN substrate 51, it is possible to store holes on the GaN substrate 51 by applying direct voltage to between the polishing pad 44 and the GaN substrate 51 through the KOH electrolyte 14. Consequently, it becomes possible to accelerate wet chemical etching of especially the p-type GaN thin film and increase the wet etching speed.

Further, this surface planarization method is different from the surface planarization method of the first embodiment in that it accelerates chemical reaction in the KOH electrolyte 14 and increases the wet etching speed by heating the KOH electrolyte 14 at the same time when heating the GaN substrate 51 by the substrate heater 47.

Consequently, in the surface planarization method and by the surface planarization device in this embodiment, the GaN substrate surface is polished using the polishing pad in the following way when the surface of the GaN substrate is polished using the polishing pad: (i) the surface of the GaN substrate is brought into contact with the alkaline electrolyte containing fine Pt particles; (ii) ultraviolet rays are irradiated on the surface of the GaN substrate that is brought into contact with the alkaline electrolyte through the openings of the polishing pad, and then (iii) direct current is further applied to between the GaN substrate surface and the polishing pad. Consequently, it becomes possible to accelerate the formation of pairs of an electron and a hole on the GaN substrate surface and the dissolution of the GaN. This makes it possible to realize, at a further higher speed, chemical etching than in the case of the surface planarization method and the surface planarization device of the first embodiment. Also, since heating the GaN substrate makes it possible to reduce the degree of the warpage of the GaN substrate, it becomes possible to perform etching and polishing with an excellent evenness on the surface. Further, since the electrolyte is also heated when the GaN substrate is heated, it becomes possible to perform, at a further higher speed, chemical etching.

### Third Embodiment

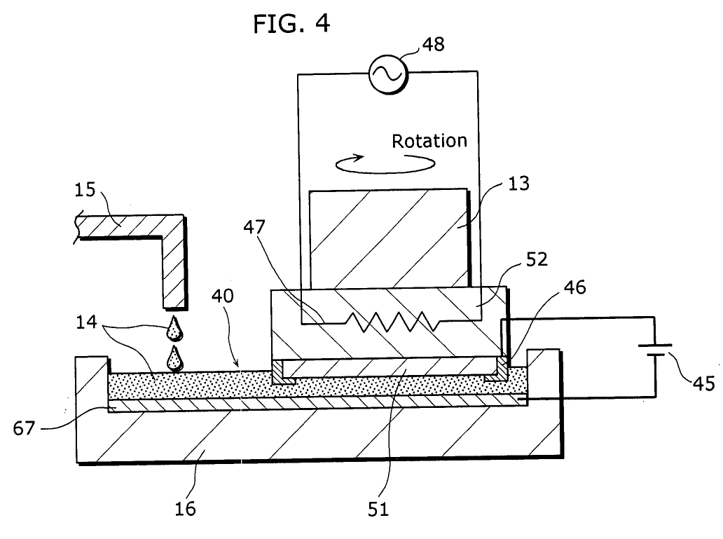

FIG. 4 is a cross-sectional view of a surface planarization device, showing the structure of the device in a third embodiment of the present invention.

This surface planarization device is for planarizing the surface of the GaN substrate 51. The surface planarization device includes (i) an electrolyte supply port 15 for supplying the KOH electrolyte 14 including fine Pt particles and an abrasive, (ii) a storage container 40, (iii) a wafer holder 52, (iv) a load 13, (v) a device housing 16, (vi) a polishing pad 67, for polishing the surface of the GaN 51, placed on the back surface of the storage container 40, (vii) a power supply 45 and (viii) electrode pins 46. The GaN substrate 51 is structured by forming a GaN thin film on a sapphire substrate using the MOCVD method.

The polishing pad 67 is placed facing the surface to be polished of the GaN substrate 51. The polishing pad 67 is an electrically-conductive member made of, for example, a metal board.

The substrate heater 47 connected with the heater power 48 is attached to the wafer holder 52.

Next, the surface planarizaion method in the third embodiment of the present invention will be described with reference to FIG. 4.

In the surface planarization device having the above structure, the surface of the GaN substrate 51 is polished and planarized by (i) placing the GaN substrate 51 on the wafer holder 52 so that the surface to be polished points downward and fixing the GaN substrate 51 using wax or the like, (ii) placing the load 13 on the GaN substrate 51 through the wafer holder 52, (iii) pressing the surface of the GaN substrate 51 on the polishing pad 67 in the KOH electrolyte 14 stored in the storage container 40, and (iv) rotating the wafer holder 52.

The surface planarization device of this embodiment has the same electric power supply and electrodes as in the case of the surface planarization device in the second embodiment. However, in the case where a p-type GaN thin film is formed on the surface of the GaN substrate 51, the surface planarization device of this embodiment applies bias so that the GaN substrate 51 side has plus potential, storing holes around the surface of the GaN substrate 51, and increases wet etching speed. In this way, it does not irradiate ultraviolet rays on the GaN substrate 51 so that wet etching speed is increased, unlike the surface planarization device of the second embodiment. This eliminates the need to use a light source that emits ultraviolet rays, and thus it becomes possible to miniaturize a surface planarization device. Also, the surface planarization device shown in this embodiment accelerates chemical wet etching of especially a p-type GaN thin film, therefore it becomes possible to perform selective etching.

### Forth Embodiment

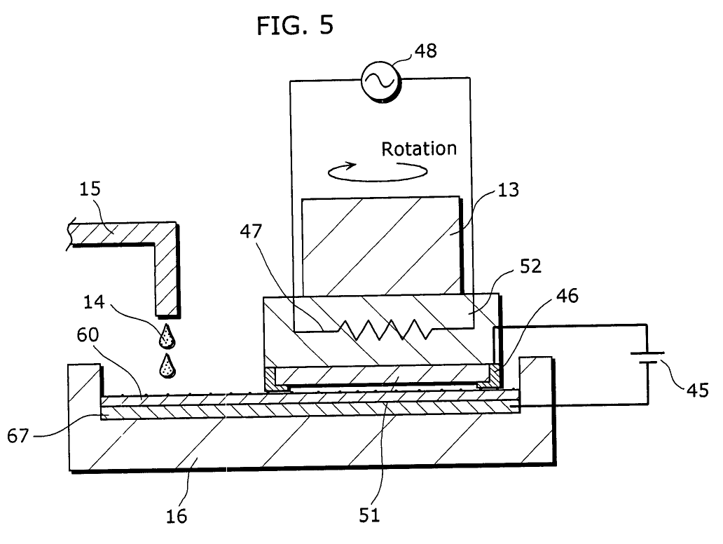

FIG. 5 is a cross-sectional view of a surface planarization device, showing the structure of the device in a fourth embodiment of the present invention.

This surface planarization device is for planarizing the surface of the GaN substrate 51. The surface planarization device includes (i) an electrolyte supply port 15 for supplying the KOH electrolyte 14 including fine Pt particles and an abrasive, (ii) a spongiform container 60 for storing the KOH electrolyte 14 supplied from the electrolyte supply port 15, (iii) a wafer holder 52, (iv) a load 13, (v) a device housing 16, (vi) a polishing pad 67, for polishing the surface of the GaN substrate 51, placed in the lower part of the spongiform container 60 so that it is brought into contact with the spongiform container 60, (vii) a power supply 45 and (viii) electrode pins 46.

The substrate heater 47 connected with the heater power 48 is attached to the wafer holder 52.

Next, the surface planarizaion method in the forth embodiment of the present invention will be described with reference to FIG. 5.

In the surface planarization device having the above structure, the surface of the GaN substrate 51 is polished and planarized by (i) placing the GaN substrate 51 on the wafer holder 52 so that the surface to be polished points downward and fixing the GaN substrate 51 using wax or the like, (ii) placing the load 13 on the GaN substrate 51 through the wafer holder 52, (iii) pressing the surface of the GaN substrate 51 on the polishing pad 67 bringing the surface of the GaN substrate 51 into contact with the spongiform container 60, and (iv) rotating the wafer holder 52.

Therefore, the surface planarization device in this embodiment can be miniaturized like the surface planarization device of the third embodiment.

### Fifth Embodiment

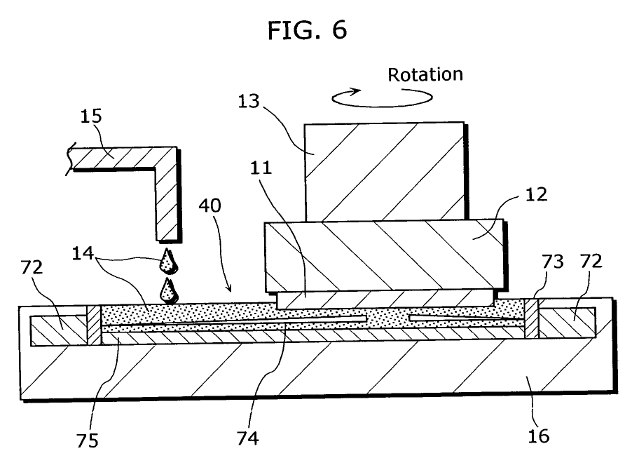

FIG. 6 is a cross-sectional view of a surface planarization device, showing the structure of the device in a fifth embodiment of the present invention.

This surface planarization device is for planarizing the surface of the GaN substrate 51. The surface planarization device includes (i) an electrolyte supply port 15 for supplying the KOH electrolyte 14 including fine Pt particles and an abrasive, (ii) a wafer holder 12, (iii) a load 13, (iv) a storage container 40, (v) an ultraviolet laser light source 72 placed at both sides of the storage container 40, (vi) a polishing pad 75, for polishing the surface of the GaN substrate 11, placed on the back surface of the storage container 40, and a device housing 16.

The ultraviolet ray laser light source 72 irradiates ultraviolet laser light 74 that has energy greater than that of the band gap of the GaN substrate 11, on the surface of the GaN substrate 11 that is brought into contact with the KOH electrolyte 14. The quartz board 73 constitutes the side parts of the storage container 40 and is placed between the ultraviolet laser light source 72 and the GaN substrate 11. The quartz board 73 is transparent to this ultraviolet laser 74, and the ultraviolet laser light 74 passes through the quartz board 73.

The polishing pad 75 is placed facing the surface to be polished of the GaN substrate 11. The polishing pad 75 is made of, for example, a metal board or a resin such as synthetic rubber.

Next, the surface planarization method in the fifth embodiment of the present invention will be described with reference to FIG. 6.

The surface planarization device having the above structure, the surface of the GaN substrate 11 is polished and planarized by (i) placing and fixing, using a wax or the like, the GaN substrate 11 on the wafer holder 12 so that the surface to be polished points downward, (ii) placing the load 13 on the GaN substrate 11 through the wafer holder 12, (iii) pressing the surface of the GaN substrate 11 on the polishing pad 75 in the KOH electrolyte 14 stored in the storage container 40, and then (iv) rotating the wafer holder 12.

At this time, this surface planarization method is different from the surface planarization method of the first embodiment in the following two points: ultraviolet laser light such as the third-order harmonic generation of YAG laser, instead of the light of a mercury vapor lamp, is used as light to be irradiated on the GaN substrate 11; and light sources are placed like an array in the peripheral part of the polishing pad 75 and the light is irradiated on the GaN substrate 11 from the sides of the GaN substrate 11 through the quartz board 73 without forming openings of the polishing pad 75. In the case of using laser light as the light to be irradiated on the GaN substrate 11, the intensity of the light to be irradiated becomes sufficiently intense, in other words, becomes more intense than that of an ultraviolet light source of, for example, a high-pressure mercury lamp. This eliminates the need to place light sources in the proximity of the surface of the GaN substrate 11 and to irradiate ultraviolet rays through the openings of the polishing pad. Consequently, it becomes possible to miniaturize a surface planarization device and to realize higher etching speed obtained especially for the n-type GaN substrate because of the strong light.

Therefore, in the surface planarization method and by the surface planarization device in this embodiment, the GaN substrate surface is brought into contact with the alkaline electrolyte containing Pt fine particles and ultraviolet laser light is irradiated on the GaN substrate surface that is brought into contact with the alkaline electrolyte from the part around the polishing pad when polishing the GaN substrate surface. Consequently, it becomes possible to accelerate the formation of pairs of an electron and a hole on the GaN substrate surface and the dissolution of the GaN. This makes it possible to realize a small surface planarizaion device that can perform chemical etching at a further higher speed than the surface planarization device of the first embodiment does.

Note that, in the surface planarization method and by the surface planarization device of the present embodiment, light irradiation on the GaN substrate surface is performed using the third-order harmonic generation of YAG laser, but He—Cd laser or Excimer Laser may be used instead at the time of this light irradiation.

### Sixth Embodiment

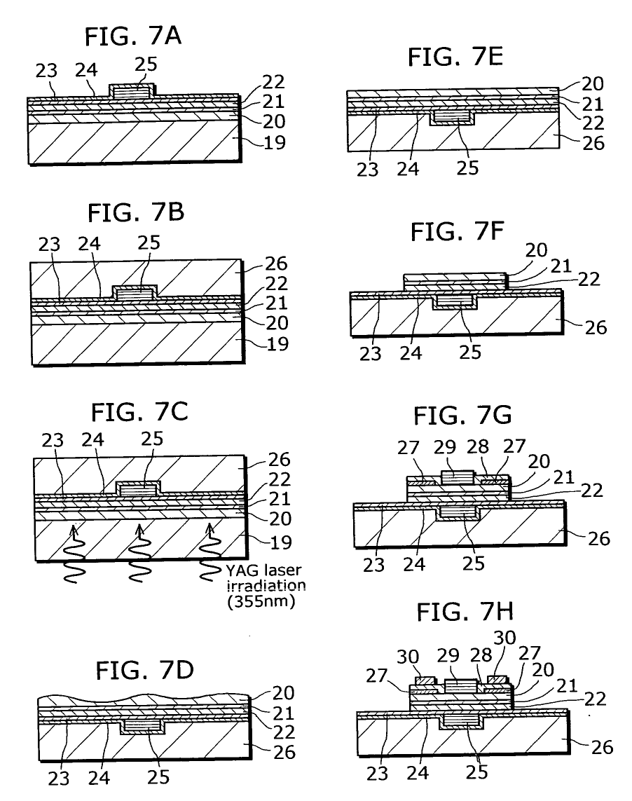

FIGS. 7A to 7H are cross-sectional views of surface emitting laser elements, indicating the manufacturing method of the element in a sixth embodiment of the present invention.

First, as shown in FIG. 7A, an n-type InGaAlN layer 20, an InGaAlN active layer 21 and a p-type InGaAlN layer 22 are formed respectively, for example, on a sapphire substrate 19 using the MOCVD method, a p-layer side ITO transparent electrode 23 is formed using the electron beam deposition method, and then an SiO₂/Ta₂O₅ multi-layer film 25 is formed using the RF sputtering method or the like. At this time, the structure of the SiO₂/Ta₂O₅ multi-layer film 25 is determined so that the reflection rate becomes big enough to the wavelength of the light to be emitted from the InGaAlN active layer 21. For example, in the case where light with a wavelength of 340 nm is emitted from the InGaAlN active layer 21, the structure is ten laminated pairs of an 80 nm SiO₂ film and a 53 nm Ta₂O₅ film. After that, a part of the SiO₂/Ta₂O₅ multi-layer film 25 is selectively removed of by wet etching in which hydrofluoric acid is used, and a Pt/Au electrode 24 is formed so that it is brought into contact with the p-layer side ITO transparent electrode 23 and the top layer of the SiO₂/Ta₂O₅ multi-layer film 25.

Next, as shown in FIG. 7B, Au plating 26 with the thickness of about 50 μm is formed on the Au layer as the ground layer with Pt/Au electrodes 24 as described earlier.

Next, as shown in FIG. 7C, the third harmonic generation with the wavelength of 355 nm of YAG laser is irradiated from the back surface of the sapphire substrate 19, scanning the substrate surface. The irradiated laser light is absorbed by not the sapphire substrate 19 but the GaN only. The local heat generated by the irradiation dissolves the combination of the GaN around the interface between the sapphire substrate 19 and the n-type InGaAlN layer 20. This is called laser lift-off technique. In this way, the sapphire substrate 19 is separated, and thus it becomes possible to obtain the device structure made of the GaN system semiconductor material.

At this time, the surface of the n-type InGaAlN layer 20 separated from the sapphire substrate 19 becomes a rough surface with a roughness of, for example, 30 nm RMS as shown in FIG. 7D. This is because the dissolution of the GaN around the interface is uneven. A conceivable reason why the surface becomes uneven like this is that the laser light has been irradiated unevenly or crystalline disorder is observed on the GaN initial growth layer formed on the sapphire substrate 19.

Next, as shown in FIG. 7E, planarization processing of this rough surface is performed using the surface planarization method and by the surface planarization device shown in the first to the fifth embodiments. In other words, etching and polishing of the surface of the n-type InGaAlN layer 20 is performed using a KOH electrolyte with an abrasive and fine Pt particles, the surface of the n-type InGaAlN layer 20 being exposed through the laser lift-off technique for separating the n-type InGaAlN layer 20 from the sapphire substrate. In this way, it is possible to perform, at high speed, such planarization of the surface that can make the surface beautifully even.

Next, as shown in FIG. 7F, etching is selectively performed on the following layers, including the SiO₂/Ta₂O₅ multi-layer 25 formed at the p-layer side: the planarized n-type InGaAlN layer 20; the InGaAlN active layer 21; and the p-type InGaAlN layer 22.

Next, as shown in FIG. 7G, the SiO₂ thin film layer 27 with an opening is formed on the planarized n-type InGaAlN layer 20. The opening of the SiO₂ thin film layer 27 is formed above the SiO₂/Ta₂O₅ multi-layer 25 formed at the p-layer side. After that, the n-layer side ITO transparent electrode 28 and the n-layer side SiO₂/Ta₂O₅ multi-layer 29 are formed. Like the case of the p-layer side SiO₂/Ta₂O₅ multi-layer 25, the n-layer side SiO₂/Ta₂O₅ multi-layer 29 is designed so that the layer has such a film thickness that can realize a big reflection rate to the wavelength of the light emitted from the InGaAlN active layer 21.

Lastly, as shown in FIG. 7H, the Ti/Au electrode 30 is formed and brought into contact with the n-layer side ITO transparent electrode 28.

Consequently, in the manufacturing method of the surface emitting laser element in this embodiment, the surface emitting laser structure made of a GaN system is formed on the sapphire substrate and the sapphire substrate is separated by irradiating a short-wavelength high-output ultraviolet pulse laser on the back surface of the sapphire substrate. After that, chemical polishing etching is performed on the InGaAlN layer surface exposed by this separation using an alkaline electrolyte with an abrasive and fine Pt particles so as to planarize the surface. This results in forming a structure like a high-reflection mirror such as a dielectric multi-layer film on the surface of the planarized InGaAlN layer. As the resulting layer has an increased reflection rate to the emitted wavelength, it becomes possible to easily realize a GaN system surface emitting laser element. In this way, it becomes possible to planarize the InGaAlN layer surface evenly and with a high reproducibility, and thus it becomes possible to form the surface emitting laser element with a high yield and a high reproducibility.

Up to this point, the surface treatment method and the surface treatment device concerning the present invention have been described based on those embodiments, but the present invention is not limited to those described embodiments. Variations and modifications can be made without deviating from the scope of the present invention.

For example, the substrate used in the first to the fifth embodiments may be replaced by any substrate such as the GaAs substrate or the InP substrate or the like other than the GaN substrate and any plane direction may be used. Also, the epitaxial growth layer that constitutes the substrate may have any composition of InGaAlN as long as it is a GaN system semiconductor. Also, it may include a V-group element such as As and P or III-group element such as B as a constituent element. Further, the crystal growth method may be one of or a combination of the following methods: the MOCVD method; the Molecular Beam Epitaxy (MBE) method; and the HVPE method. Further, the epitaxial growth layer may be formed on any of the following substrates: SiC; GaN; ALN; MgO; LiGaO₂; LiALO₂; and a mixed crystal of LiGaO₂ and LiALO₂.

Also, the surface planarization method and the surface planarization device in the respective embodiments may be used (i) after the device structure such as a semiconductor laser element, a light emitting diode element and an electric field transistor element is formed or (ii) in the process for planarizing the epitaxial growth layer during the process for structuring one of the above-listed devices.

Although only some exemplary embodiments of this invention have been described in detail above, those skilled in the art will readily appreciate that many modifications are possible in the exemplary embodiments without materially departing from the novel teachings and advantages of this invention. Accordingly, all such modifications are intended to be included within the scope of this invention.

### INDUSTRIAL APPLICABILITY

The surface treatment method and the surface treatment device concerning the present invention can be applied for the substrate surface planarization method and the substrate surface planarization device. In the surface of the substrate one of the following is formed: a semiconductor laser element, made of a nitride semiconductor, for a high-density optical disc; a light emitting diode element for various display or lightning; and a field effect transistor integrated circuit for high frequency communication or large electrical power. They can also be applied for polishing or etching process of the surfaces of devices like recited above, and thus the surface treatment method and the surface treatment device of the present invention are very applicable.

1. A surface treatment method for planarizing a surface of a substrate, comprising
planarizing of the surface of the substrate by performing etching of the surface using an electrolyte containing fine metal particles in a way that the surface is brought into contact with the electrolyte.

2. The surface treatment method according to claim 1,
wherein the etching is performed together with irradiation of light on the surface of the substrate that is brought into contact with the electrolyte.

3. The surface treatment method according to claim 2,
wherein energy of the light to be irradiated on the surface of the substrate is greater than a band gap of the substrate.

4. The surface treatment method according to claim 2,
wherein the light to be irradiated on the surface of the substrate is a laser light.

5. The surface treatment method according to claim 1,
wherein the surface of the substrate is brought into contact with the electrolyte by impregnating the surface of the substrate into the electrolyte or by bringing the surface of the substrate into contact with a surface of a holding member into which the electrolyte is infiltrated.

6. The surface treatment method according to claim 1,
wherein the fine metal particles are made of one of Pt, Au and Ag.

7. The surface treatment method according to claim 1,
wherein the electrolyte includes an abrasive, and
the etching is performed together with polishing of the surface of the substrate.

8. The surface treatment method according to claim 1,
wherein an electrically conductive member is placed in the electrolyte, and
the etching of the surface of the substrate is performed together with application of voltage to between the surface and the electrically conductive member.

9. The surface treatment method according to claim 1,
wherein the etching of the surface of the substrate is performed together with heating of the substrate.

10. The surface treatment method according to claim 1,
wherein the substrate is made of a compound semiconductor including nitrogen.

11. A surface treatment device for planarizing a surface of a substrate, comprising:
a storage unit operable to store an electrolyte containing fine metal particles; and
a contact unit operable to bring the surface of the substrate into contact with the electrolyte.

12. The surface treatment device according to claim 11, further comprising
a light source for irradiating light on the surface of the substrate.

13. The surface treatment device according to claim 12,
wherein the light source is a laser light source.

14. The surface treatment device according to claim 11,
wherein said storage unit is a storage container having an opening on the top surface and is for storing the electrolyte, and
said contact unit is operable to fix the substrate and operable to impregnate the surface of the substrate into the electrolyte in the storage container.

15. The surface treatment device according to claim 11,
wherein said storage unit is a holding member into which the electrolyte is infiltrated, and
said contact unit is operable to fix the substrate and operable to bring the surface of the substrate into contact with the holding member.

16. The surface treatment device according to claim 11, further comprising
a polishing pad for polishing the surface of the substrate, the pad being placed facing the surface.

17. The surface treatment device according to claim 11, further comprising
a polishing pad for polishing the surface of the substrate, the pad being placed facing the surface of the substrate, and
a light source for irradiating light on the surface of the substrate, the light source being placed opposite the substrate across the polishing pad,
wherein the polishing pad has an opening.

18. The surface treatment device according to claim 11,
wherein said storage unit is a storage container having an opening on the top surface and is for storing the electrolyte,
said contact unit is operable to fix the substrate and operable to impregnate the surface of the substrate into the electrolyte in the storage container,
the surface treatment device further comprises:
a polishing pad for polishing the surface of the substrate, the polishing pad being placed facing the surface; and
a light source for irradiating the light on the surface of the substrate, the light source being placed at a side of the storage container; and
a side surface of the storage container is transparent to the light emitted by the light source.

19. The surface treatment device according to claim 11, further comprising:
an electrically conductive polishing pad for polishing the surface of the substrate, the polishing pad being placed facing the surface;
electrodes placed in contact with the substrate; and
an electronic power supply for applying voltage to between the electrodes and the polishing pad.

20. The surface treatment device according to claim 11, further comprising a heater for heating the substrate.
